(19) United States
(12) Patent Application Publication
(10) Pub. No.: US 2006/0170011 A1
(43) Pub. Date: Aug. 3, 2006

(54) Semiconductor device and manufacturing method thereof

(76) Inventors: Toshifumi Irisawa, Tokyo (JP); Toshinori Numata, Kamakura-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/235,168

(22) Filed: Sep. 27, 2005

(30) Foreign Application Priority Data
Jan. 31, 2005 (JP) 2005-024494

(51) Int. Cl. H01L 29/768

(52) U.S. Cl. 257/250

(57) ABSTRACT

A semiconductor device includes a gate-all-around MOSFET structure comprises a first semiconductor layer which is formed on a support substrate and which has a recess formed on a surface thereof, a second semiconductor layer formed on the first semiconductor layer and which has a part thereof formed to cross over the recess of the first semiconductor layer, a gate electrode which is formed through a gate insulation film to surround the crossing portion of the second semiconductor layer and which has parts other than the part located under the second semiconductor layer processed in a gate pattern, source and drain areas formed on the second semiconductor layer, and a sidewall insulation film which is formed on sidewall surfaces of the recess of the first semiconductor layer and which has a greater thickness than the gate insulation film.

### CROSS-REFERENCE TO RELATED APPLICATIONS

This application is based upon and claims the benefit of priority from prior Japanese Patent Application No. 2005-024494, filed Jan. 31, 2005, the entire contents of which are incorporated herein by reference.

### BACKGROUND OF THE INVENTION

1. Field of the Invention

This invention relates to a semiconductor device of a MOS structure and, more particularly, to a semiconductor device comprising a hollow area in a semiconductor substrate, i.e. having a SON (Silicon on Nothing) structure and a manufacturing method of the semiconductor device.

2. Description of the Related Art

In a SON structure comprising a hollow layer inside a Si substrate, the smallest parasitic capacitance can be implemented in a substrate formed of Si since the relative dielectric constant of the hollow layer is 1. Similarly to a SOI (Silicon on Insulator) structure in which a silicon oxide film is embedded, an element area can be protected by the hollow layer, from carriers generated by cosmic rays. In addition, the SON structure has high process matching property with a gate-all-around MOSFET which is most excellent in the immunity to short channel effect, of currently proposed MOSFETS. For this reason, the SON structure is hopeful in application to a high-performance ultra small MOSFET.

On the other hand, it is known that the condition of the band structure is changed due to influence of in-plane tensile strain and the mobility of Si subjected to epitaxial growth on SiGe is increased as compared with unstrained Si. Thus, it is expected that a high-speed low-power-consumption LSI can be implemented by combining strained Si and the SON structure.

In a conventional manufacturing method of the SON structure, for example, surface atoms are diffused by thermal treatment after digging a trench on a Si substrate (Document 1: T. Sato, “SON-MOSFET using ESS (Empty Space in Silicon) technique for SoC applications”, Technical Digest of International Electrical Devices Meeting, pp. 809-812, 2001). According to another conventional method, SiGe is selectively etched in the Si/SiGe structure (Document 2: S. Monfray, “First 80 nm SON-MOSFETs with perfect morphology and high electrical performance”, Technical Digest of International Electrical Devices Meeting, pp. 645-648, 2001). It has been clarified, however, that a SON substrate having preferable strained Si cannot be manufactured in these methods.

In the method of Document 1, high-temperature thermal treatment of 1000° C. or higher needs to be carried out to induce Si migration. Since Ge is easily diffused in surface Si at such a high temperature, the strained Si structure cannot be maintained.

In the method of Document 2, overetching easily occurs and the Si bridge of the SON area thereby collapses, at the time of etching the SiGe. Moreover, if the SON substrate is applied to the gate-all-around MOSFET, a leak current is easily generated between the source and drain. In other words, selectively forming an insulation layer varied in thickness on a Si bridge and a semiconductor layer supporting the Si bridge has not been disclosed. For this reason, according to the prior art, a gate insulation film is formed simultaneously on the Si bridged and the semiconductor layer supporting the Si bridge, forming a uniform and preferable insulation film is difficult at the cavity portion due to the complicated structure, and leak current is increased at the angular portion due to concentration of the electric field.

As described above, in the conventional manufacturing method of the SON structure, manufacturing a strained SON structure of high yield and high quality is difficult, and manufacturing a preferable gate-all-around MOSFET is difficult.

### BRIEF SUMMARY OF THE INVENTION

An aspect of the present invention is a semiconductor device comprising a support substrate, a first semiconductor layer formed on the support substrate, a top surface of the first semiconductor layer having a recess or hole formed thereon, a second semiconductor layer formed on the first semiconductor layer, a part of the second semiconductor layer crossing the recess or hole of the first semiconductor layer, a gate electrode formed via a gate insulation film to surround the crossing portion of the second semiconductor layer, the gate electrode being processed in a gate pattern, a portion immediately under the second semiconductor layer being processed in like pattern of the second semiconductor layer, source and drain areas formed on the second semiconductor layer in association with the gate pattern, and a sidewall insulation film formed on a sidewall surface of the recess or hole of the first semiconductor layer, having a thickness greater than a thickness of the gate insulation film.

Another aspect of the present invention is a semiconductor device comprising a support substrate, a first semiconductor layer formed in an shape of separated islands or formed to have insular protrusions, on the support substrate, a second semiconductor layer formed on the first semiconductor layer, having a part formed to connect adjacent islands or adjacent protrusions to each other, a gate electrode formed via a gate insulation film to surround the crossing portion of the second semiconductor layer, the gate electrode being processed in a gate pattern, a portion immediately under the second semiconductor layer being processed in like pattern of the second semiconductor layer, source and drain areas formed on the second semiconductor layer in association with the gate pattern, and a sidewall insulation film formed on a sidewall surface of the first semiconductor layer, having a thickness greater than a thickness of the gate insulation film.

Still another aspect of the present invention is a method of manufacturing a semiconductor device, comprising-forming a second semiconductor layer on a first semiconductor layer, selectively etching the first and second semiconductor layers on both sides of a channel formation area of a transistor so as to make the channel formation area linear, forming an oxide film on sidewall surfaces of the first semiconductor layer exposed by the etching, so as to oxidize an overall body of the first semiconductor layer in the channel formation area, forming a cavity portion under the second semiconductor layer in the channel formation area by removing the oxide film, forming a gate electrode through a gate insulation film so as to surround the second semiconductor layer in the channel formation area, processing the gate electrode in a gate pattern and conducting processing, immediately under the second semiconductor layer, in a pattern equal to a pattern of the second semiconductor layer, and forming source and drain areas on the second semiconductor layer in association with the gate pattern.

Further another aspect of the present invention is a method of manufacturing a semiconductor device, comprising forming a second semiconductor layer on a first semiconductor layer, selectively etching the first and second semiconductor layers on both sides of a channel formation area of a transistor so as to make the channel formation area linear, forming an oxide film on sidewall surfaces of the first semiconductor layer exposed by the etching, so as to oxidize an overall body of the first semiconductor layer in the channel formation area, a thickness of the oxide film in the channel formation area being greater than a thickness of the oxide film in areas other than the channel formation area, forming a cavity portion under the second semiconductor layer in the channel formation area by removing the oxide film, while leaving a part of the oxide film on the sidewall surfaces of the first semiconductor layer, forming a gate electrode through a gate insulation film so as to surround the second semiconductor layer in the channel formation area, processing the gate electrode in a gate pattern and conducting processing, immediately under the second semiconductor layer, in a pattern equal to a pattern of the second semiconductor layer, and forming source and drain areas on the second semiconductor layer in association with the gate pattern.

### BRIEF DESCRIPTION OF THE SEVERAL VIEWS OF THE DRAWING

FIG. 1 shows a plan view and a cross-sectional view illustrating a schematic structure of a semiconductor device according to a first embodiment;

FIG. 2 shows a plan view and a cross-sectional view illustrating SON structure according to the first embodiment;

FIGS. 3A to 3C show cross-sectional views illustrating steps of manufacturing the SON structure according to the first embodiment;

FIG. 4 shows a plan view and a cross-sectional view illustrating a schematic structure of a semiconductor device according to a second embodiment;

FIGS. 5A to 5C show cross-sectional views illustrating steps of manufacturing the SON structure according to the second embodiment;

FIG. 6 shows a plan view and a cross-sectional view illustrating a strained SON structure of a semiconductor device according to a third embodiment;

FIGS. 7A and 7B show cross-sectional views illustrating steps of manufacturing the strained SON structure of the semiconductor device according to the third embodiment;

FIGS. 8A to 8C show cross-sectional views illustrating steps of manufacturing the strained SON structure of the semiconductor device according to the third embodiment;

FIGS. 9A and 9B show perspective views illustrating a processing pattern of a semiconductor layer according to a modified embodiment of the present invention; and

FIG. 10 shows a perspective view illustrating a SON pattern according to a modified embodiment of the present invention.

### DETAILED DESCRIPTION OF THE INVENTION

Embodiments of the present invention will be explained below with reference to the accompanying drawings.

### First Embodiment

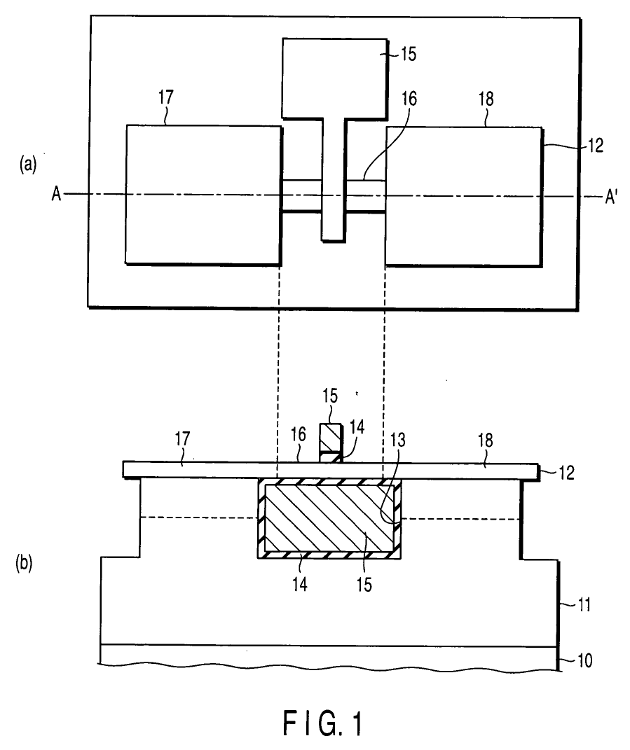

FIG. 1 illustrates a schematic structure of a semiconductor device according to a first embodiment. FIG. 1(a) shows a plan view and FIG. 1(b) shows a cross-sectional view seen along line A-A′ of FIG. 1(a).

A strain-relaxed SiGe layer (first semiconductor layer) 11 is formed on a support substrate 10. A groove portion (cavity portion) 13 is formed by selectively etching a surface portion of the SiGe layer 11. The groove portion 13 is formed such that the SiGe layer 11 has two island-shaped protrusions spaced from each other with a predetermined distance. A strained Si layer (second semiconductor layer) 12 is formed on the protrusions of the SiGe layer 11. A part of the strained Si layer 12 is formed to cross the groove portion 13 formed between the two protrusions.

A gate electrode 15 is formed via a gate insulation film 14 so as to surround the strained Si layer 12 positioned above the groove portion 13. Most parts of the gate electrode 15 are processed in a gate pattern, but the gate electrode 15 is formed to fill the groove portion 13 immediately under the strained Si layer 12. A source area 17 and a drain area 18 are formed on the strained Si layer 12 so as to sandwich a channel area 16 determined by the gate electrode 15.

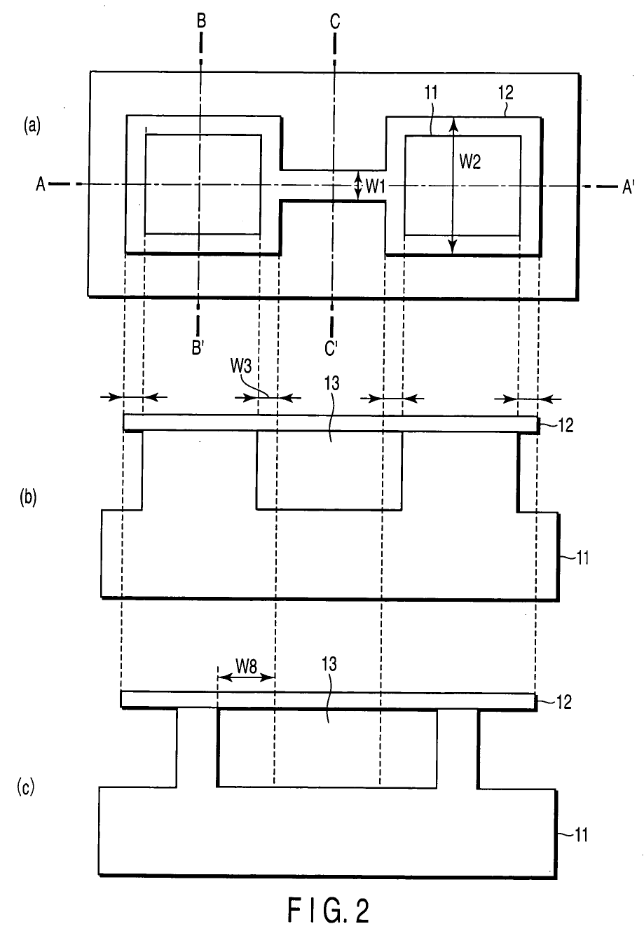

FIG. 2 illustrates a SON structure of the present embodiment. FIG. 2(a) shows a plan view and FIG. 2(b) shows a view of A-A′ cross-section of FIG. 2(a).

The strained Si layer 12 is formed on the SiGe layer 11 having a higher oxidation speed than Si and the SiGe layer 11 is partially removed under the strained Si layer 12. In other words, the drawing shows what is called a strained SON structure, having the groove portion 13 at a part of the SiGe layer 11 under the strained Si layer 12. W1 represents a channel width, W2 represents a source/drain width, and W3 represents an overetching width.

For comparison, the SON structure manufactured in the method of Document 2 is shown in FIG. 2(c). In the method of Document 2, after the strained Si layer 12 and the SiGe layer 11 are processed in the element area pattern by photolithography, anisotropic etching and the like, the SiGe layer 11 under the strained Si layer 12 is subjected to isotropic etching. The hollow area 13 of the SON structure is thereby formed. The area which supports the strained Si layer 12 in the SON structure is designed to be wider than an area which is to be SON, such that the SiGe layer 11 serving as the support layer remains even if the SiGe layer 11 under the SON is etched.

To certainly remove the SiGe layer 11 in the area which is to be SON, however, the etching amount of SiGe must have a margin and, thus, the SiGe layer 11 serving as the support layer needs to be further etched. For this reason, overetching width W8 greater than the overetching width W3 of FIG. 2(b). Therefore, the distance of the Si bridge between the support layers becomes longer by the hollow portion formed by the processing margin, and the Si bridge often collapses. In addition, the processing damage caused by etching is serious.

To solve such a problem that the Si bridge in the SON area is easily broken down by overetching, the present embodiment employs a process of oxidizing the SiGe layer and removing the oxidized portion.

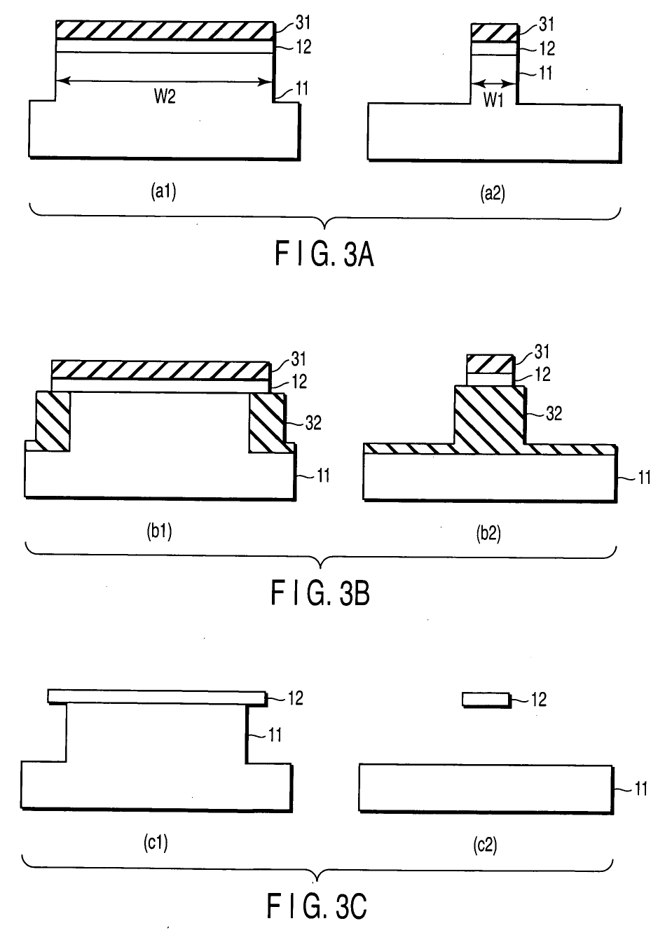

FIGS. 3A to 3C show cross-sectional views illustrating steps of manufacturing the SON structure according to the present embodiment. In the drawings, (a1), (b1) and (c1) correspond to B-B′ cross-section of FIG. 2(a), and (a2), (b2) and (c2) correspond to C-C′ cross-section of FIG. 2(a).

The relaxed SiGe layer 11 may be subjected to epitaxial growth on the Si substrate which serves as the support substrate 10 or on the SOI substrate. In addition, the relaxed SiGe layer 11 may be formed by employing both the epitaxial growth and a recently proposed oxidation and concentration (T. Tezuka, “A Novel Fabrication Technique of Ultrathin and Relaxed SiGe Buffer Layers with High Ge Fraction for Sub-100 nm Strained Silicon-on-Insulator MOSFETs”, Japanese Journal of Applied Physics, Vol. 40, pp. 2866-2874, 2001). The manufacturing method is not limited to these methods. The strained Si layer 12 is formed on the relaxed SiGe layer 11 by epitaxial growth.

First, an active area of the device is formed on the strained Si substrate manufactured as described above, as shown in FIG. 3A. The active area may have an arbitrary shape, but the active area is formed such that the width W2 of the area which is to be source/drain is greater than the width Wi of the area which is to the channel at the manufacturing of the transistor. To form the active area, the strained Si layer 12 and the SiGe layer 11 are subjected to selective etching by using a mask layer 31 formed of, for example, a Si oxide film, Si nitride film or the like.

Next, a SiGe oxide 32 is formed by oxidizing side surfaces of the SiGe layer 11 as shown in FIG. 3B. The oxidation is conducted until the SiGe oxide 32 extends under the strained Si layer 12 in the C-C′ cross-section of FIG. 2(a). More specifically, the oxidation is conducted at a temperature of 850° C. or lower at which diffusion of Ge in Si is not noticeable, in an atmosphere containing steam. If the oxidation is conducted under such conditions, the strain-relaxed SiGe layer 11 alone can be oxidized at a high selection ratio without almost oxidizing the strained Si layer 12 since strain-relaxed SiGe has an oxidation speed of thirty times or more to Si.

Next, the strained SON structure is formed by peeling off the SiGe oxide 32 and the mask layer 31 by wet etching, as shown in FIG. 3C. The structure in this state corresponds to that in FIG. 2. The oxidation of the SiGe layer has a characteristic that since Ge is concentrated in an interface between the oxide film and the SiGe layer, Ge composition in the vicinity of the SiGe surface is higher than the original Ge composition in the SiGe layer after peeling off the SiGe oxide.

In the present embodiment, as described above, the strained SON structure can be formed by only conducting oxidation and peeling of the oxide film, i.e. very simple and highly controllable processes after formation of the active area. For this reason, overetching width W3 can be easily reduced as compared with the manufacturing method employing selective plasma etching of SiGe or the like. In addition, since in-plane uniformity is improved and the silicon oxide film can be etched at a high selection ratio to silicon, processing damage can be reduced.

Therefore, high-quality strained SON structure can be manufactured at high yield and a preferable gate-all-around MOSFET can be produced.

### Second Embodiment

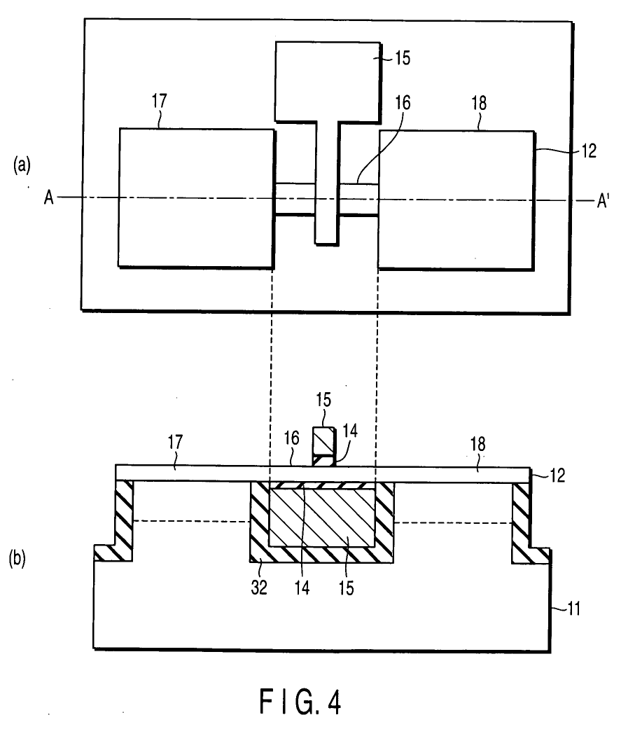

FIG. 4 illustrates a semiconductor device according to a second embodiment. FIG. 4(a) shows a plan view and FIG. 4(b) shows a view of A-A′ cross-section of FIG. 4(a). Elements like or similar to those shown in FIG. 1 are denoted by similar reference numbers and their detailed explanations are omitted here.

The groove portion 13 and the relaxed SiGe layer 11 are in contact with each other in the first embodiment, but the SiGe oxide 32 may be left therebetween as shown in FIG. 4. In this case, since the gate electrode 15 and the source/drain 17, 18 are insulated from each other by the SiGe oxide 32, in the gate-all-around MOSFET, the leak current flowing between the gate and the source/drain can be reduced as compared with a case of insulating the gate electrode 15 and the source/drain 17, 18 by the thin gate insulation film 14 alone.

The above-described structure can be implemented in the following manner.

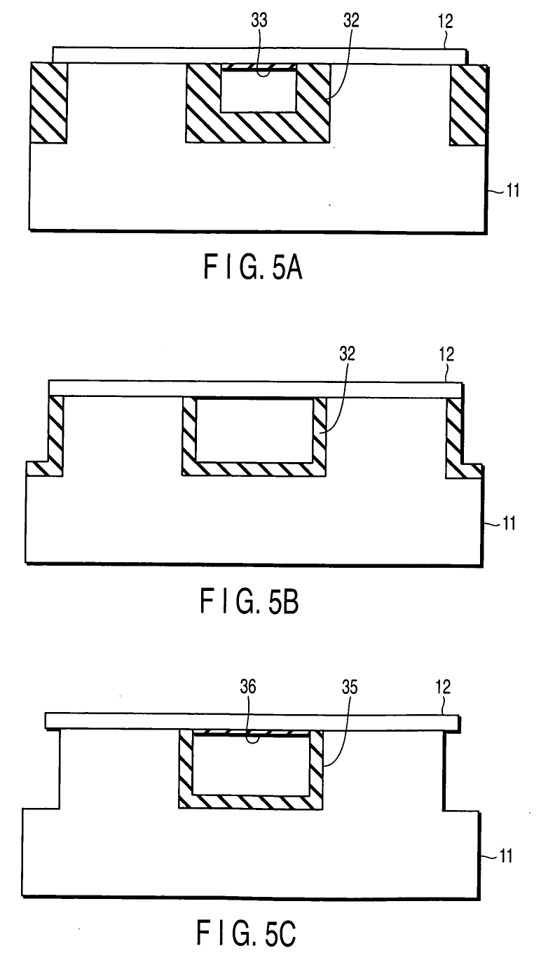

In the step of oxidizing the side surfaces of the SiGe layer 11 as shown in FIG. 3B, the oxidation is conducted for a longer time than that conducted until the SiGe oxide 32 extends under the strained Si layer 12. Then, the SiGe oxide 32 is formed as shown in FIG. 5A. At this time, a thin Si oxide 33 is also formed on the surface of the strained Si layer 12.

Next, wet etching is conducted, and the SiGe oxide 32 under the strained Si layer 12 is thereby completely removed as shown in FIG. 3C (c2). However, the SiGe oxide 32 on the side surfaces of the relaxed SiGe layer 11 is left at the other portions as shown in FIG. 5B. After that, the same structure as that shown in FIG. 4 can be obtained by forming the gate insulation film 14, forming the gate electrode 15 and conducting the patterning.

After the SiGe oxide 32 is completely removed as shown in FIG. 3C, a SiGe oxide may be newly formed. In this case, a SiGe oxide 35 is formed by wet oxidation as shown in FIG. 5C, in the state shown in FIG. 2(b). At this time, since oxidation of Si is very slower than SiGe, a Si oxide 36 on the surface of the Si layer 12 has a thickness of approximately 2 nm even if the oxide 35 on the side surfaces of the SiGe layer 11 is formed to have a thickness of, for example, 60 nm. Thus, the Si oxide 36 alone can be removed by processing the surface of the Si layer 12 with rare hydrofluoric acid as pretreatment conducted before formation of the gate insulation film 14. After that, the same structure as that shown in FIG. 4 can be obtained by forming the gate insulation film 14, forming the gate electrode 15 and conducting the patterning.

In the present embodiment, as described above, the strained SON structure can be formed by only conducting oxidation and peeling of the oxide film, i.e. very simple and highly controllable processes after formation of the active area and the same advantage as that of the first embodiment can be obtained. Moreover, since the sidewall insulation film 32 of a low dielectric constant material having a greater thickness than the gate insulation film 14 is formed on the sidewall surface of the relaxed SiGe layer 11, the gate electrode 15 under the strained Si layer 12 is insulated from the source/drain by the sidewall insulation film 32. Therefore, the leak current flowing between the gate and the source/drain can be reduced without operation delay as compared with a case of insulating the gate electrode and the source/drain by the thin gate insulation film 14 alone.

### Third Embodiment

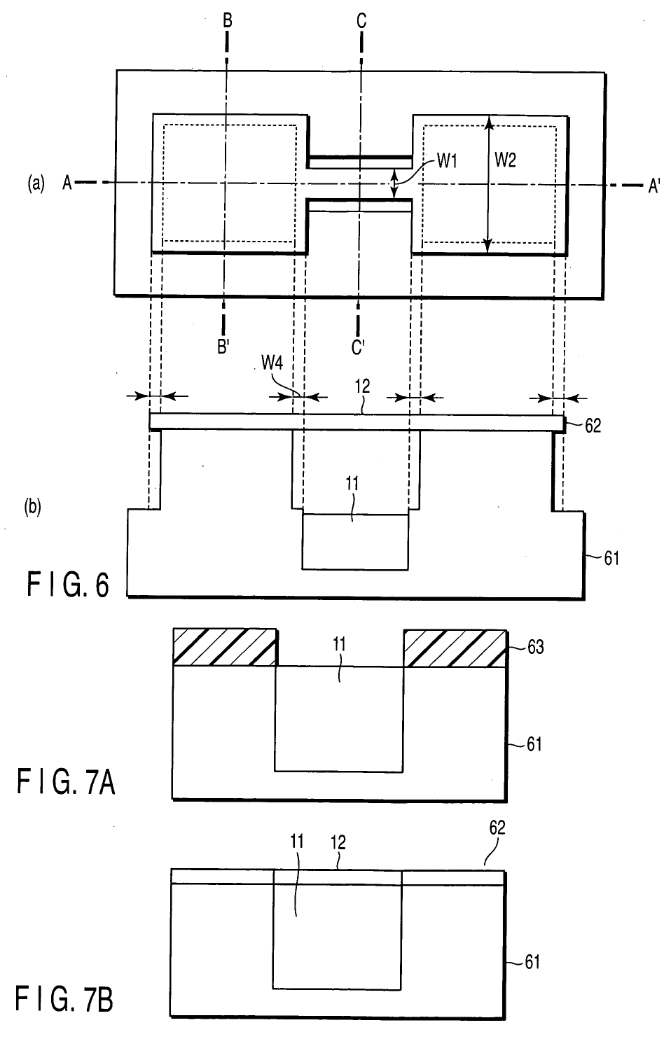

FIG. 6 illustrates a strained SON structure of a semiconductor device according to a second embodiment. FIG. 6(a) shows a plan view and FIG. 6(b) shows a view of A-A′ cross-section of FIG. 6(a). Elements like or similar to those shown in FIG. 1 are denoted by similar reference numbers and their detailed explanations are omitted here.

The present embodiment has a strained SON structure in which the strained Si layer 12 and strain-relaxed Si layer 62 are formed on a strained SiGe layer 61 and the cavity portion 13 exists under the strained Si layer 12.

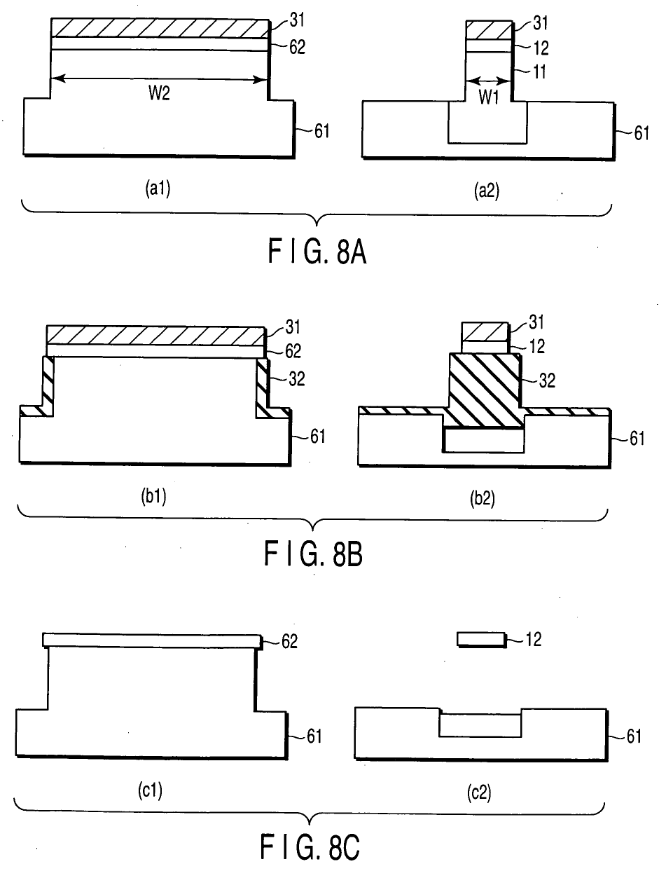

To explain the process of manufacturing the strained SON structure according to the present embodiment, main steps are shown in schematic views of FIGS. 7A, 7B, and FIGS. 8A to 8C.

FIGS. 7A, 7B correspond to A-A′ cross-section of FIG. 6(a), (a1), (b1) and (c1) of FIGS. 8A to 8C correspond to B-B′ cross-section of FIG. 6(a), and (a2), (b2) and (c2) of FIGS. 8A to 8C correspond to C-C′ cross-section of FIG. 6(a).

First, as shown in FIG. 7A, ion implantation is selectively conducted on the strained SiGe layer 61 in the area which is to be the cavity portion 13, by using, for example, a mask layer 63 of resist or the like to relax the strain in this area, and the relaxed SiGe layer 11 is thereby formed. The strained SiGe layer 61 is formed by epitaxial growth on, for example, a Si substrate or SOI substrate.

Next, as shown in FIG. 7B, Si is subjected to epitaxial growth after removing the mask layer 63. The strained Si layer 12 is formed on the relaxed SiGe layer 11. The strain-relaxed Si layer 62 is formed on the strained SiGe layer 61.

Next, as shown in FIG. 8A, an active area of tie device is formed in a partially strained Si substrate formed as described above. The active area may have an arbitrary shape and, unlike the first embodiment, does not have a limitation that width W2 must be greater than width W1. The active area is formed by selective etching using the mask layer 31 formed of, for example, a Si oxide film or Si nitride film.

Next, as shown in FIG. 8B, oxidization of the SiGe layer 11 is conducted until the SiGe oxide 32 extends under the strained Si layer 12 in the C-C′ cross-section of FIG. 6(a). The oxidation is conducted at a temperature of 850° C. or lower at which diffusion of Ge in Si is not noticeable, in an atmosphere containing steam. If the oxidation is conducted under such conditions, the strain-relaxed SiGe layer 11 alone can be oxidized at a high selection ratio without almost oxidizing the strained Si layer 12 and strained SiGe layer 61 since strain-relaxed SiGe has an oxidation speed of thirty times or more and seven times or more to Si and strained SiGe, respectively.

Next, the strained SON structure is formed by peeling off the SiGe oxide 32 and the mask layer 31 by wet etching, as shown in FIG. 8C. The structure in this state corresponds to that in FIG. 6.

In the present embodiment, the groove portion 13 and the relaxed SiGe layer 11 are in contact with each other, but the SiGe oxide 32 may be left therebetween similarly to the first embodiment. In this case, the gate electrode 15 and the source/drain 17, 18 are insulated from each other by the SiGe oxide 32, as shown in FIG. 4, in the gate-all-around MOSFET. For this reason, the leak current flowing between the gate and the source/drain can be reduced as compared with a case of insulating the gate electrode 15 and the source/drain 17, 18 by the thin gate insulation film 14 alone.

In the present embodiment, an area which does not serve as the cavity portion is the strained SiGe layer 61 and the oxidization speed of the strained SiGe is approximately one quarter of the relaxed SiGe. Therefore, overetching width W4 shown in FIG. 6 can be more reduced as compared with the first embodiment.

### Modified Embodiment

The present invention is not limited to the embodiments described above. In the embodiments, the Si substrate or SOI substrate is used as the support substrate, but any substrate allowing the first semiconductor layer to be grown up can be used. The first semiconductor layer is formed of SiGe and the second semiconductor layer is formed of Si, but the semiconductor materials can be arbitrarily be changed in accordance with conditions.

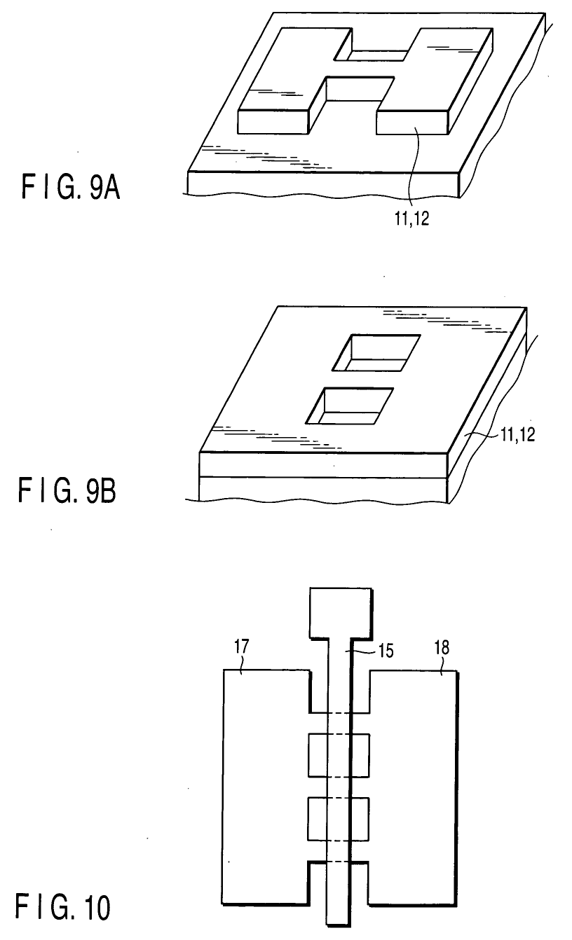

In addition, the first and second semiconductor layers are formed such that the source/drain and channel areas protrude as shown in FIG. 9A. In the present invention, however, the hollow area may be formed by removing the first semiconductor layer under the channel area. Thus, the first and second semiconductor layers may be removed on both sides of the channel area alone, as shown in FIG. 9B.

One channel area is formed between the source and drain. As shown in FIG. 10, however, the gate width can be made equivalently greater by providing a plurality of channel areas.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a support substrate;
a first semiconductor layer formed on the support substrate, a top surface of the first semiconductor layer including a recess or hole formed thereon;
a second semiconductor layer formed on the first semiconductor layer, and including a portion crossing the recess or hole of the first semiconductor layer;
a gate electrode disposed around the portion of the second semiconductor layer with a gate insulation film interposed between the gate electrode and the portion of the second semiconductor layer, the-gate electrode being processed in a gate pattern, and a portion of the gate electrode which is immediately under the second semiconductor layer being processed in same pattern as that of the second semiconductor layer;
source and drain areas formed on the second semiconductor layer corresponding to the gate pattern being arranged between the source and drain areas; and
a sidewall insulation film formed on a sidewall surface of the recess or hole of the first semiconductor layer and having a thickness greater than a thickness of the gate insulation film.

2. The apparatus according to claim 1, wherein the first semiconductor layer is formed of monocrystalline SiGe and the second semiconductor layer is formed of Si.

3. The apparatus according to claim 1, wherein the first semiconductor layer is formed of monocrystalline SiGe of relaxed lattice strain and the second semiconductor layer is formed of Si having lattice strain.

4. The apparatus according to claim 1, wherein the first semiconductor layer is formed of monocrystalline SiGe, the second semiconductor layer is formed of Si, and the sidewall insulation film is formed of a SiGe oxide.

5. The apparatus according to claim 1, wherein at least the portion of the second semiconductor layer is formed of a semiconductor layer having lattice strain.

6. A semiconductor device comprising:
a support substrate;
a first semiconductor layer formed on the support substrate and having a plurality of separated islands or insular protrusions;
a second semiconductor layer formed on the first semiconductor layer, and including a portion formed to connect adjacent ones of the separated islands or the insular protrusions to each other;
a gate electrode disposed around the portion of the second semiconductor layer with a gate insulation film interposed between the gate electrode and the portion of the second semiconductor layer, the gate electrode being processed in a gate pattern, and a portion of the gate electrode which is immediately under the second semiconductor layer being processed in same pattern as that of the second semiconductor layer;
source and drain areas formed on the second semiconductor layer corresponding to the gate pattern being arranged between the source and drain areas; and
a sidewall insulation film formed on a sidewall surface of the first semiconductor layer and having a thickness greater than a thickness of the gate insulation film.

7. The apparatus according to claim 6, wherein the first semiconductor layer is formed of monocrystalline SiGe and the second semiconductor layer is formed of Si.

8. The apparatus according to claim 6, wherein the first semiconductor layer is formed of monocrystalline SiGe of relaxed lattice strain and the second semiconductor layer is formed of Si having lattice strain.

9. The apparatus according to claim 6, wherein the first semiconductor layer is formed of monocrystalline SiGe, the second semiconductor layer is formed of Si, and the sidewall insulation film is formed of a SiGe oxide.

10. The apparatus according to claim 6, wherein at least the portion of the second semiconductor layer is formed of a semiconductor layer having lattice strain.

11. A method of manufacturing a semiconductor device, comprising:
forming on a first semiconductor layer a second semiconductor layer;
selectively etching the first semiconductor layer and the second semiconductor layer on both sides of a channel formation area of a transistor to be fabricated on the second semiconductor layer to form a linear channel formation area;
forming an oxide film on sidewall surfaces of the first semiconductor layer exposed by the etching and at a time oxidizing an overall portion of the first semiconductor layer which is in the linear channel formation area;
removing the oxide film and the oxidized portion of the first semiconductor layer to form a cavity portion under the second semiconductor layer in the linear channel formation area;
forming a gate electrode around the second semiconductor layer in the linear channel formation area with a gate insulation film interposed between the gate electrode and the second semiconductor layer;
processing the gate electrode in a gate pattern and processing a portion of the gate electrode which is immediately under the second semiconductor layer in same pattern as that of the second semiconductor layer; and
forming source and drain areas on the second semiconductor layer corresponding to the gate pattern being arranged between the source and drain areas.

12. The method according to claim 11, wherein the selectively etching includes etching from a surface side of the second semiconductor layer to a middle portion of the first semiconductor layer.

13. The method according to claim 11, wherein the selectively etching is conducted in anisotropic etching based on RIE and removing the oxide film and the oxidized portion is conducted in isotropic etching based on wet etching.

14. A method of manufacturing a semiconductor device, comprising:
forming on a first semiconductor layer a second semiconductor layer;
selectively etching the first semiconductor layer and the second semiconductor layer on both sides of a channel formation area of a transistor to be fabricated on the first semiconductor layer and the second semiconductor layer to form a linear channel formation area;
forming an oxide film on sidewall surfaces of the first semiconductor layer exposed by the etching and at a time oxidizing an overall portion of the first semiconductor layer in the linear channel formation area, a thickness of a first portion of the oxide film in an area other than the linear channel formation area being greater than a thickness of a second portion of the oxide film in the linear channel formation area;
removing the oxide film and the oxidized overall portion to form a cavity portion under the second semiconductor layer in the linear channel formation area, while leaving a part of the oxide film on the sidewall surfaces of the first semiconductor layer;
forming a gate electrode around the second semiconductor layer in the linear channel formation area with a gate insulation film interposed between the gate electrode and the second semiconductor layer;
processing the gate electrode in a gate pattern and processing a portion of the gate electrode which is immediately under the second semiconductor layer in same pattern as that of the second semiconductor layer; and
forming source and drain areas on the second semiconductor layer corresponding to the gate pattern being arranged between the source and drain areas.

15. The method according to claim 14, wherein the selectively etching includes etching from a surface side of the second semiconductor layer to a middle portion of the first semiconductor layer.

16. The method according to claim 14, wherein the selectively etching is conducted in anisotropic etching based on RIE and removing the oxide film and the oxidized portion is conducted in isotropic etching based on wet etching.

17. A method of manufacturing a semiconductor device, comprising:
forming on a first semiconductor layer a second semiconductor layer;
selectively etching the first semiconductor layer and the second semiconductor layer on both sides of a channel formation area of a transistor to be fabricated on the first semiconductor layer and the second semiconductor layer to form a linear channel formation area;
forming a first oxide film on sidewall surfaces of the first semiconductor layer exposed by the etching and at time, oxidizing an overall portion of the first semiconductor layer which is in the linear channel formation area;
removing the first oxide film and the oxidizing overall portion to form a cavity portion under the second semiconductor layer in the linear channel formation area;
forming a second oxide film on the sidewall surfaces of the first semiconductor layer exposed to the cavity portion due to formation of the cavity portion;
forming a gate electrode around the second semiconductor layer in the linear channel formation area with a gate insulation film interposed between the gate electrode and the second semiconductor layer;
processing the gate electrode in a gate pattern and processing a portion of the gate electrode which is immediately under the second semiconductor layer in same pattern as that of the second semiconductor layer; and
forming source and drain areas on the second semiconductor layer corresponding to the gate pattern being arranged between the source and drain areas.

18. The method according~to claim 17, wherein to etch the first and second semiconductor layers, etching is conducted from the surface side of the second semiconductor layer to a middle portion of the first semiconductor layer.

19. The method according to claim 17, wherein the etching of the first and second semiconductor layers is conducted in anisotropic etching based on RIE and the etching of the oxide films is conducted in isotropic etching based on wet etching.

20. A method of manufacturing a semiconductor device, comprising:
forming on a first semiconductor layer a second semiconductor layer;
selectively removing portions of the first semiconductor layer and the second semiconductor layer while leaving other portions of the first semiconductor layer and the second semiconductor layer which correspond to source and drain formation areas of a transistor to be fabricated on the first semiconductor layer and the second semiconductor layer and a linear channel formation area which connects the source and drain formation areas to each other and which has a smaller width than the source and drain formation areas;
forming an oxide film on each of sidewall surfaces of a remaining portion of the first semiconductor layer in the source and drain formation areas and the channel formation area and at a time oxidizing an overall of the remaining portion of the first semiconductor layer which is in the linear channel formation area;
removing the oxide film and the overall of the remaining portion to form a cavity portion under the second semiconductor layer in the channel formation area;
forming a gate electrode around the second semiconductor layer in the linear channel formation area with a gate insulation film interposed between the gate electrode and the second semiconductor layer;
processing the gate electrode in a gate pattern and processing a portion of the gate electrode which is immediately under the second semiconductor layer in same pattern as that of the second semiconductor layer; and
forming source and drain areas on the second semiconductor layer corresponding to the gate pattern being arranged between the source and drain areas.

21. The method according to claim 20, wherein the selectively etching includes etching from a surface side of the second semiconductor layer to a middle portion of the first semiconductor layer.

22. The method according to claim 20, wherein the selectively etching is conducted in anisotropic etching based on RIE and removing the oxide film and the oxidized portion is conducted in isotropic etching based on wet etching.
